(19) United States
(12) Patent Application Publication
(10) Pub. No.: US 2025/0176309 A1
(43) Pub. Date: May 29, 2025

(54) METHOD FOR MANUFACTURING STRETCHABLE DISPLAY DEVICE USING SELF-ASSEMBLE METHOD

(71) Applicant: ELECTRONICS AND TELECOMMUNICATIONS RESEARCH INSTITUTE, Daejeon (KR)

(72) Inventors: Doo-Hee CHO, Daejeon (KR); Jae Bon KOO, Daejeon (KR); Chan Woo PARK, Daejeon (KR); Seongdeok AHN, Daejeon (KR)

(73) Assignee: ELECTRONICS AND TELECOMMUNICATIONS RESEARCH INSTITUTE, Daejeon (KR)

(21) Appl. No.: 18/917,813

(22) Filed: Oct. 16, 2024

(30) Foreign Application Priority Data
Nov. 24, 2023 (KR) 10-2023-0165748

(51) Int. Cl. H01L 33/00; H01L 23/544

(52) U.S. Cl. CPC H10H 20/01; H01L 23/544; H01L 2223/54426; H10H 20/036

(57) ABSTRACT

An embodiment of the inventive concept provides a method for manufacturing a stretchable display device. The method includes manufacturing first to third unit devices including first to third alignment key patterns, respectively, each of which is provided in a pair and which are different in distance between the pair, mounting the first to third unit devices, by using a self-assemble method, on a transfer substrate having trenches which accommodate the first to third alignment key patterns, and transferring the first to third unit devices to a stretchable substrate.

### CROSS-REFERENCE TO RELATED APPLICATIONS

This U.S. non-provisional patent application claims priority under 35 U.S.C. § 119 of Korean Patent Application No. 10-2023-0165748, filed on Nov. 24, 2023, the entire contents of which are hereby incorporated by reference.

### BACKGROUND

The present disclosure herein relates to a method for manufacturing a display device, and more particularly, to a method for manufacturing a stretchable display device using a self-assemble method.

Recently, interests about free-form displays are increasing. The free-form displays mean displays capable of being stretched, twisted, folded, and bent freely. Typical flexible displays may form only two-dimensional curved surfaces (cylindrical curved surfaces) and thus are not applicable to curved surfaces three-dimensionally bent (spherical curved surfaces). In order to make display apparatuses having been flat to have three-dimensional curved surfaces, displays themselves need to be elastically stretched. Displays elastically stretched and contracted in all directions are referred to as stretchable displays, and are recently embodied using LED microchips and special silicone resin substrates.

### SUMMARY

The present disclosure provides a method for manufacturing a stretchable display device capable of increasing production reliability.

An embodiment of the inventive concept provides a method for manufacturing a stretchable display device. The method includes manufacturing first to third unit devices including first to third alignment key patterns, respectively, each of which is provided in a pair and which are different in distance between the pair, mounting the first to third unit devices, by using a self-assemble method, on a transfer substrate having trenches which accommodate the first to third alignment key patterns, and transferring the first to third unit devices to a stretchable substrate.

In an embodiment, each of the first alignment key patterns may include a first wide key pattern, and a first narrow key pattern which is narrower than the first wide key pattern and spaced a first distance from the first wide key pattern.

In an embodiment, each of the second alignment key patterns may include a second wide key pattern, and a second narrow key pattern which is narrower than the second wide key pattern and spaced a second distance less than the first distance from the second wide key pattern.

In an embodiment, each of the third alignment key patterns may include a third wide key pattern, and a third narrow key pattern which is narrower than the third wide key pattern and spaced a third distance less than the second distance from the third wide key pattern.

In an embodiment, the first unit device may further include a substrate having a rectangular shape. The first wide key pattern and the first narrow key pattern may be arranged in a diagonal direction of the rectangular shape.

In an embodiment, the first to third unit devices may be provided in a fluid and aligned on the transfer substrate.

In an embodiment, the first to third unit devices may be provided in mask holes, respectively, and aligned on the transfer substrate.

In an embodiment, the first unit device may include a red light emitting layer, the second unit device may include a green light emitting layer, and the third unit device may include a blue light emitting layer.

In an embodiment, each of the trenches may include a wide trench and a narrow trench narrower than the wide trench.

In an embodiment, the first to third unit devices may further include first to third ferromagnet layers provided on the first to third alignment key patterns, respectively.

In an embodiment of the inventive concept, a method for manufacturing a stretchable display device includes manufacturing first unit devices each including first alignment key patterns spaced a first distance from each other, manufacturing second unit devices each including second alignment key patterns spaced a second distance less than the first distance from each other, manufacturing third unit devices each including third alignment key patterns spaced a third distance less than the second distance from each other, aligning the first to third unit devices, by using a self-assemble method, on a transfer substrate having trenches which accommodate the first to third alignment key patterns, and transferring the first to third unit devices to a stretchable substrate.

In an embodiment, the manufacturing of the first unit devices may include forming the first unit devices each including a first color light emitting layer on a first substrate, forming, on a bottom surface of the first substrate, the first alignment key patterns including a first wide key pattern and a first narrow key pattern spaced the first distance from the first wide key pattern, and cutting the first substrate to individually divide the first unit devices.

In an embodiment, the manufacturing of the first unit devices may further include heating the first alignment key patterns, and forming a first ferromagnet layer on the bottom surface of the first substrate and the first alignment key patterns.

In an embodiment, the manufacturing of the second unit devices may include forming the second unit devices each including a second color light emitting layer on a second substrate, forming, on a bottom surface of the second substrate, the second alignment key patterns including a second wide key pattern and a second narrow key pattern spaced the second distance from the second wide key pattern, and cutting the second substrate to individually divide the second unit devices.

In an embodiment, the manufacturing of the second unit devices may further include heating the second alignment key patterns, and forming a second ferromagnet layer on the bottom surface of the second substrate and the second alignment key patterns.

In an embodiment, the manufacturing of the third unit devices may include forming the third unit devices each including a third color light emitting layer on a third substrate, forming, on a bottom surface of the third substrate, the third alignment key patterns including a third wide key pattern and a third narrow key pattern spaced the third distance from the third wide key pattern, and cutting the third substrate to individually divide the third unit devices.

In an embodiment, the manufacturing of the third unit devices may further include heating the third alignment key patterns, and forming a third ferromagnet layer on the bottom surface of the third substrate and the third alignment key patterns.

In an embodiment, each of the trenches may include a wide trench and a narrow trench narrower than the wide trench.

In an embodiment, the first to third alignment key patterns may each include a photoresist pattern.

In an embodiment, the transfer substrate may include an alignment pattern having the trenches, and the alignment pattern may include a photoresist pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart illustrating a method for manufacturing a stretchable display device according to an embodiment of the inventive concept;

FIG. 2 is a flowchart illustrating a step of manufacturing first unit devices according to an embodiment;

FIGS. 3 to 5 are cross-sectional views of a process for first unit devices;

FIG. 6 is a plan view illustrating a first substrate, first wide key patterns, and first narrow key patterns in FIG. 5 according to an embodiment;

FIG. 7 is a flowchart illustrating a step of manufacturing second unit device according to an embodiment;

FIGS. 8 to 10 are cross-sectional views of a process for second unit devices;

FIG. 11 is a flowchart illustrating a step of manufacturing third unit devices according to an embodiment;

FIGS. 12 to 14 are cross-sectional views of a process for third unit devices;

FIGS. 15 to 19 are cross-sectional views of processes of mounting and transferring the first unit device, the second unit device, and the third unit devices in FIGS. 5, 10, and 14;

FIG. 20 is a flowchart illustrating a step of manufacturing the first unit devices in FIG. 4 according to an embodiment;

FIGS. 21 to 23 are cross-sectional views of a process for the first unit devices in FIG. 4;

FIG. 24 is a flowchart illustrating of a step of manufacturing the second unit devices in FIG. 9 according to an embodiment;

FIGS. 25 to 27 are cross-sectional views of a process for the second unit devices in FIG. 9;

FIG. 28 is a flowchart illustrating a step of manufacturing the third unit devices in FIG. 13 according to an embodiment;

FIGS. 29 to 31 are cross-sectional views of a process for the third unit devices in FIG. 13; and

FIG. 32 is a cross-sectional view illustrating a first unit device, a second unit device, and a third unit device, and a transfer substrate in FIG. 16 according to an embodiment.

### DETAILED DESCRIPTION

Hereinafter, embodiments of the inventive concept will be described in detail with reference to the accompanying drawings. Advantages and features of the present invention, and implementation methods thereof will be clarified through following embodiments described in detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. Like reference numerals refer to like elements throughout.

The terminology used herein is for the purpose of describing embodiments only and is not intended to be limiting of the invention. As used herein, the singular forms are intended to include the plural forms as well, unless the context clearly indicates otherwise. It will be further understood that the terms “comprises” and/or “comprising”, when used in this specification, specify the presence of stated components, operations, and/or elements, but do not preclude the presence or addition of one or more other components, operations, and/or elements. Since preferred embodiments are provided below, the order of the reference numerals given in the description is not limited thereto.

Additionally, the embodiments herein will be described with reference to cross-sectional views and/or plan views as ideal exemplary views of the present invention. In the drawings, the thicknesses of layers and regions are exaggerated for effective description of the technical contents. Accordingly, shapes of the exemplary views may be modified according to manufacturing techniques and/or allowable errors. Therefore, the embodiments of the inventive concept are not limited to the specific shape illustrated in the views, but may include other shapes created according to manufacturing processes.

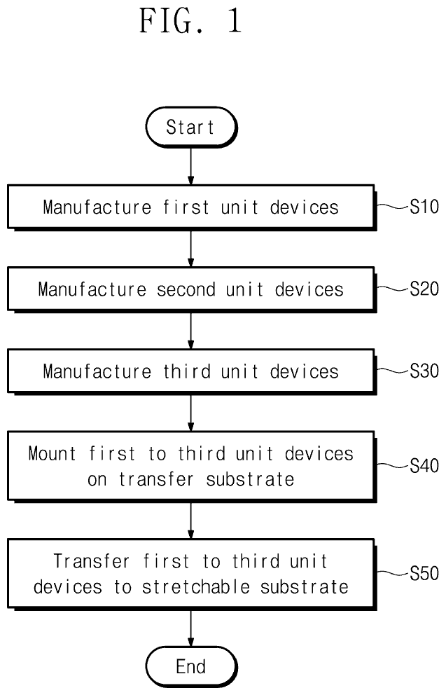

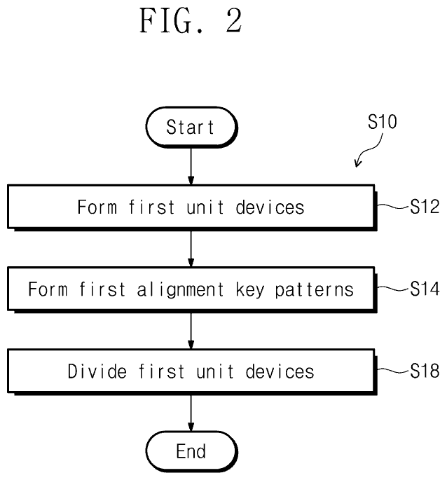

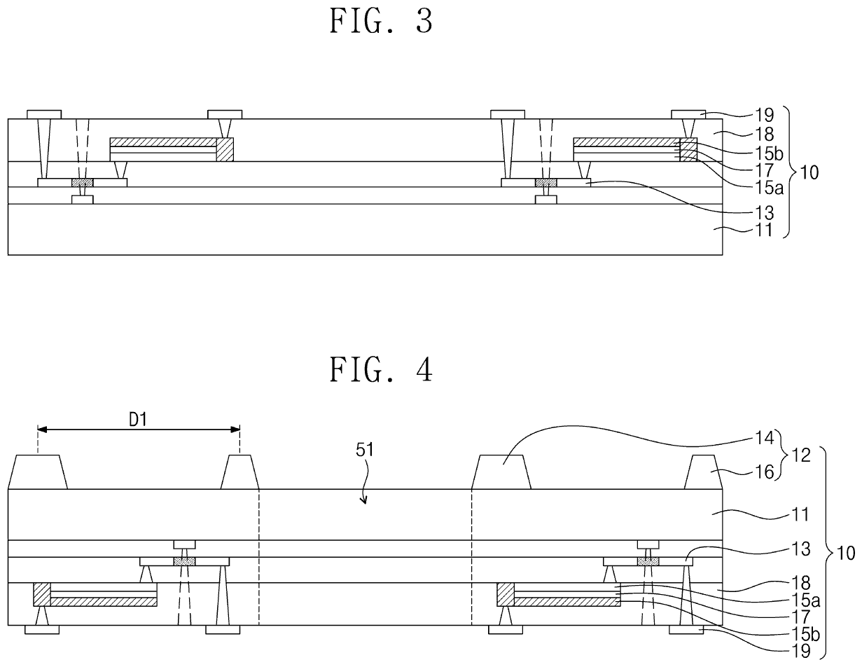

FIG. 1 illustrates a method for manufacturing a stretchable display device according to an embodiment of the inventive concept. FIG. 2 illustrates a step of manufacturing first unit devices according to an embodiment (S10). FIGS. 3 to 5 are cross-sectional views of a process for the first unit devices.

Referring to FIGS. 1 and 3, first unit devices 10 are manufactured (S10). The first unit devices 10 may include a red organic light emitting diode or a red light emitting diode.

Referring to FIGS. 2 and 3, the first unit devices 10 are formed (S12). The first unit devices 10 may be formed through a plurality of unit processes. Each of the unit processes may include a thin film deposition process, a photolithography process, and an etching process. According to an embodiment, each of the first unit devices 10 may include a first substrate 11, a first thin film transistor 13, a first lower electrode 15a, a first light emitting layer 17, a first upper electrode 15b, a first dielectric layer 18, and a first pad 19. The first light emitting layer 17 may include a red light emitting layer. A layered structure of the first unit devices 10 corresponds to a general matter and will not be described herein.

Referring to FIGS. 2 and 4, first alignment key patterns 12 are formed on a bottom surface of the first substrate 11 (S14). Each of the first alignment key patterns 12 may have a shape protruding from the substrate. The first alignment key patterns 12 may have the same height. The first alignment key patterns 12 may include a photoresist pattern. According to an embodiment, each of the first alignment key patterns 12 may include a first wide key pattern 14 and a first narrow key pattern 16. The first wide key pattern 14 may be provided on one side of each of the first unit devices 10. The first wide key pattern 14 may be wider or thicker than the first narrow key pattern 16. A center of the first narrow key pattern 16 may be provided at a first distance D1 from a center of the first wide key pattern 14. The first narrow key pattern 16 may be provided on one side of each of the first unit devices 10.

Referring to FIGS. 2, 4, and 5, a portion of the first unit device 10 including the first substrate 11 and the first dielectric layer 18 is cut to individually divide the first unit devices 10 (S18). The first substrate 11 and the first dielectric layer 18 may have a first cutting region 51 between the first unit devices 10. The first cutting region 51 of the first substrate 11 and the first dielectric layer 18 may be removed through a laser cutting process, a sawing process, or an etching process. Each of the first unit devices 10 may have a thickness of about 100 μm or less.

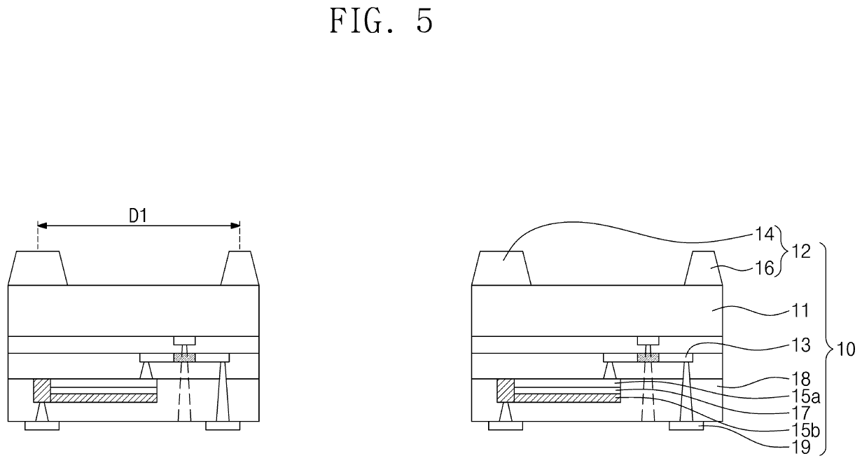

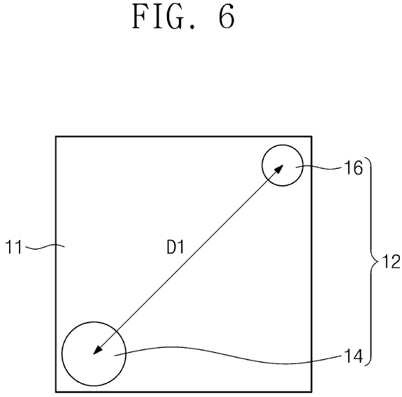

FIG. 6 is a plan view of FIG. 5 and illustrates the first substrate 11, the first wide key pattern 14, and the first narrow key pattern 16 according to an embodiment.

Referring to FIG. 6, the first substrate 11 may have a rectangular shape on a plan view, and the first wide key pattern 14 and the first narrow key pattern 16 may be arranged in a diagonal direction of the rectangular shape. The first wide key pattern 14 may be provided to be adjacent to a corner of one side of the first substrate 11 in the diagonal direction. A center of the first narrow key pattern 16 may be provided at a first distance D1 from a center of the first wide key pattern 14, and be provided to be adjacent to a corner of the other side of the first substrate 11. Each of the first unit devices 10 may include the first wide key pattern 14 and the first narrow key pattern 16 as a pair.

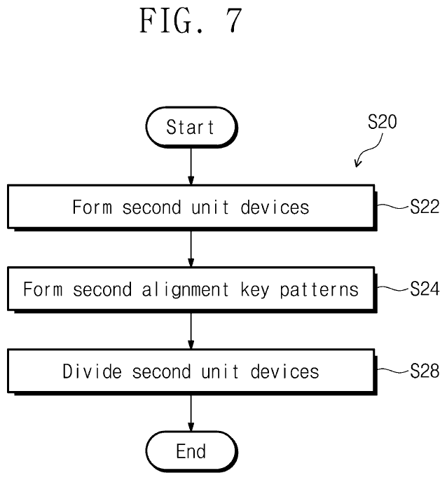

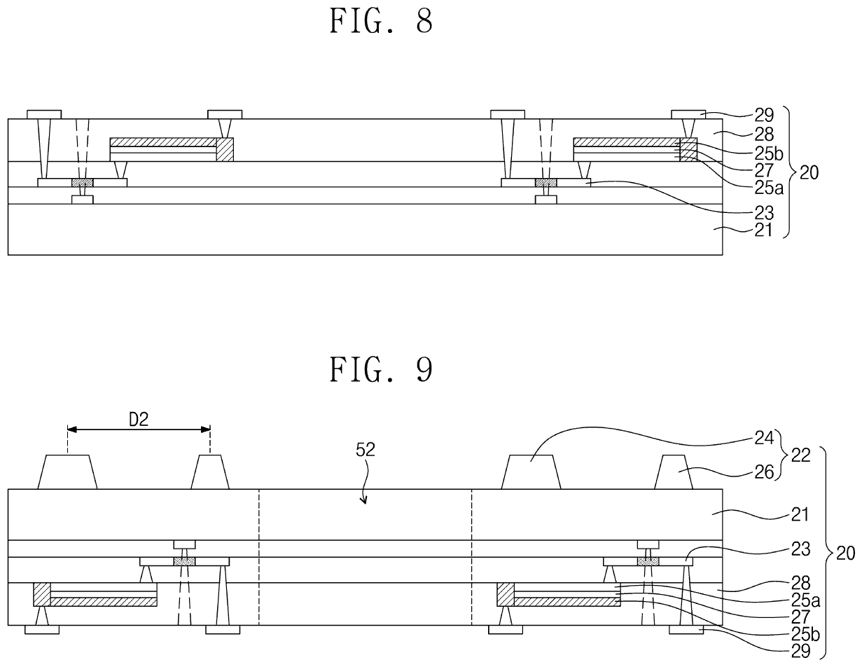

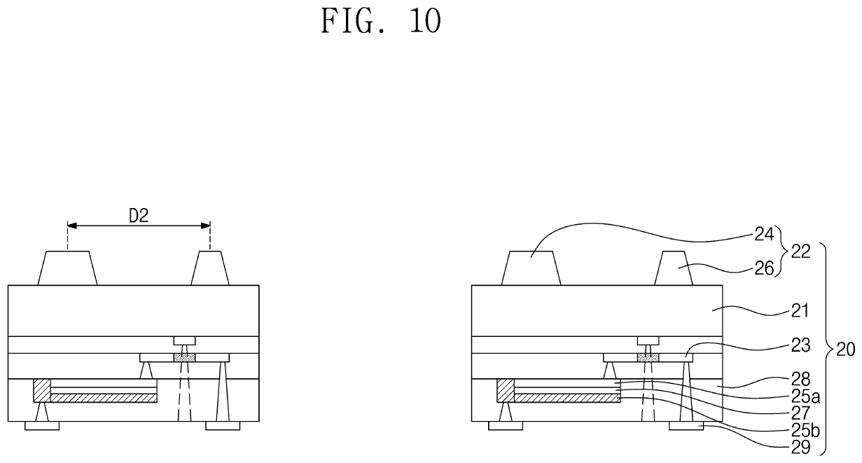

FIG. 7 illustrates a step of manufacturing second unit devices 20 according to an embodiment (S20). FIGS. 8 to 10 are cross-sectional views of a process for the second unit devices 20.

Referring to FIGS. 1 and 8, the second unit devices 20 are manufactured (S20). The second unit devices 20 may include a green organic light emitting diode or a green light emitting diode.

Referring to FIGS. 7 and 8, the second unit devices 20 are formed (S22). The second unit devices 20 may be formed through a plurality of unit processes. According to an embodiment, each of the second unit devices 20 may include a second substrate 21, a second thin film transistor 23, a second lower electrode 25a, a second light emitting layer 27, a second upper electrode 25b, a second dielectric layer 28, and a second pad 29. The second light emitting layer 27 may include a green light emitting layer.

Referring to FIGS. 7 and 9, second alignment key patterns 22 are formed on a bottom surface of the second substrate 21 (S24). Each of the second alignment key patterns 22 may have a shape protruding from the substrate. The second alignment key patterns 22 may have the same height. The second alignment key patterns 22 may include a photoresist pattern. According to an embodiment, each of the second alignment key patterns 22 may include a second wide key pattern 24 and a second narrow key pattern 26. The second wide key pattern 24 may be provided on one side of the second unit device 20. The second wide key pattern 24 may be wider or thicker than the second narrow key pattern 26. A center of the second narrow key pattern 26 may be provided at a second distance D2 from a center of the second wide key pattern 24. The second distance D2 may be less than the first distance D1. The second narrow key pattern 26 may be provided on one side of the second unit device 20.

Referring to FIGS. 7, 9, and 10, a portion of the second unit device 20 including the second substrate 21 and the second dielectric layer 28 is cut to individually divide the second unit devices 20 (S28). The second substrate 21 and the second dielectric layer 28 may have a second cutting region 52 between the second unit devices 20. The second cutting region 52 may be removed through a laser cutting process, a sawing process, or an etching process. Each of the second unit devices 20 may have a thickness of about 100 μm or less.

Although not illustrated, like the first substrate 11, the second substrate 21 may have a rectangular shape on a plan view, and the second wide key pattern 24 and the second narrow key pattern 26 may be arranged in a diagonal direction of the rectangular shape. The second wide key pattern 24 may be provided to be adjacent to a corner of one side of the second substrate 21 in the diagonal direction. A center of the second narrow key pattern 26 may be provided at a second distance D2 from a center of the second wide key pattern 24, and be provided to be adjacent to a corner of the other side of the second substrate 21.

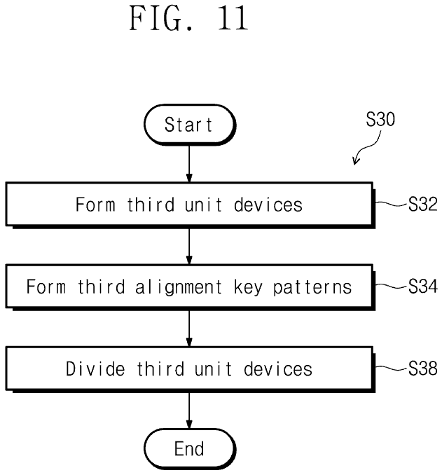

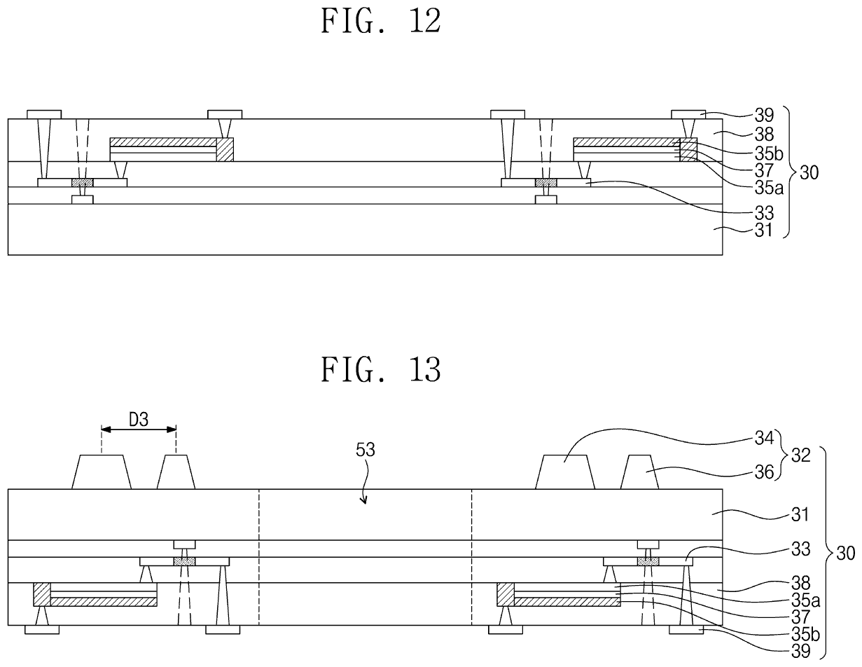

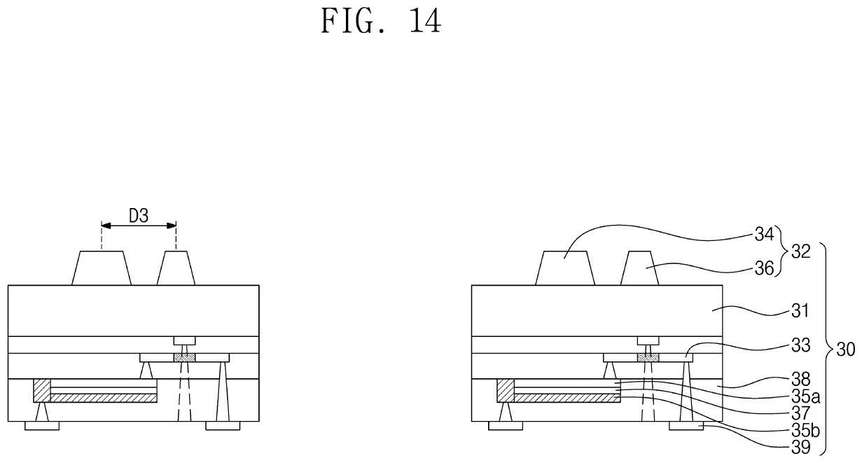

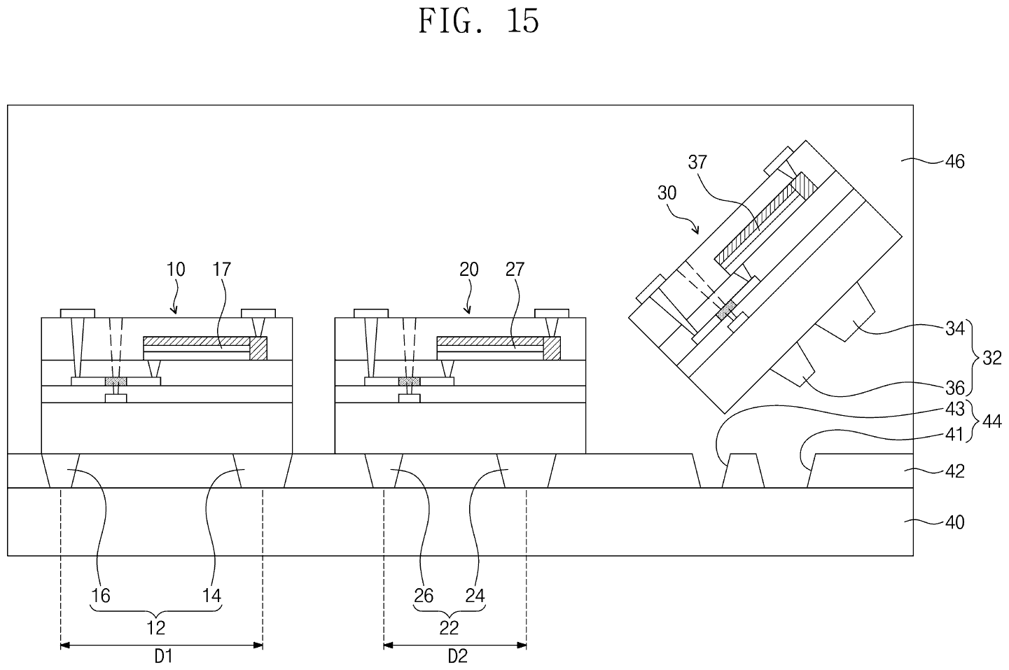

FIG. 11 illustrates a step of manufacturing third unit devices 30 according to an embodiment (S30). FIGS. 12 to 14 are cross-sectional views of a process for the third unit devices 30.

Referring to FIGS. 1 and 12, the third unit devices 30 are manufactured (S30). The third unit devices 30 may include a blue organic light emitting diode or a blue light emitting diode.

Referring to FIGS. 11 and 12, the third unit devices 30 are manufactured (S32). The third unit devices 30 may be formed through a plurality of unit processes. According to an embodiment, each of the third unit devices 30 may include a third substrate 31, a third thin film transistor 33, a third lower electrode 35a, a third light emitting layer 37, a third upper electrode 35b, a third dielectric layer 38, and a third pad 39. The third light emitting layer 37 may include a blue light emitting layer.

Referring to FIGS. 11 and 13, third alignment key patterns 32 are formed on a bottom surface of the third substrate 31 (S34). Each of the third alignment key patterns 32 may have a shape protruding from the substrate. The third alignment key patterns 32 may have the same height. The third alignment key patterns 32 may include a photoresist pattern. According to an embodiment, each of the third alignment key patterns 32 may include a third wide key pattern 34 and a third narrow key pattern 36. The third wide key pattern 34 may be provided on one side of the third unit device 30. The third wide key pattern 34 may be wider or thicker than the third narrow key pattern 36. A center of the third narrow key pattern 36 may be provided at a third distance D3 from a center of the third wide key pattern 34. The third distance D3 may be less than the second distance D2. The third narrow key pattern 36 may be provided on one side of the third unit device 30.

Referring to FIGS. 11, 13, and 14, a portion of the third unit device 30 including the third substrate 31 and the third dielectric layer 38 is cut to individually divide the third unit devices 30 (S38). The third substrate 31 and the third dielectric layer 38 may have a third cutting region 53 between the third unit devices 30. The third cutting region 53 may be removed through a laser cutting process, a sawing process, or an etching process. Each of the third unit devices 30 may have a thickness of about 100 μm or less.

Although not illustrated, the third substrate 31 may have a rectangular shape on a plan view, and the third wide key pattern 34 and the third narrow key pattern 36 may be arranged in a diagonal direction of the rectangular shape. The third wide key pattern 34 may be provided to be adjacent to a corner of one side of the third substrate 31 in the diagonal direction. A center of the third narrow key pattern 36 may be provided at a third distance D3 from a center of the third wide key pattern 34, and be provided to be adjacent to a corner of the other side of the third substrate 31.

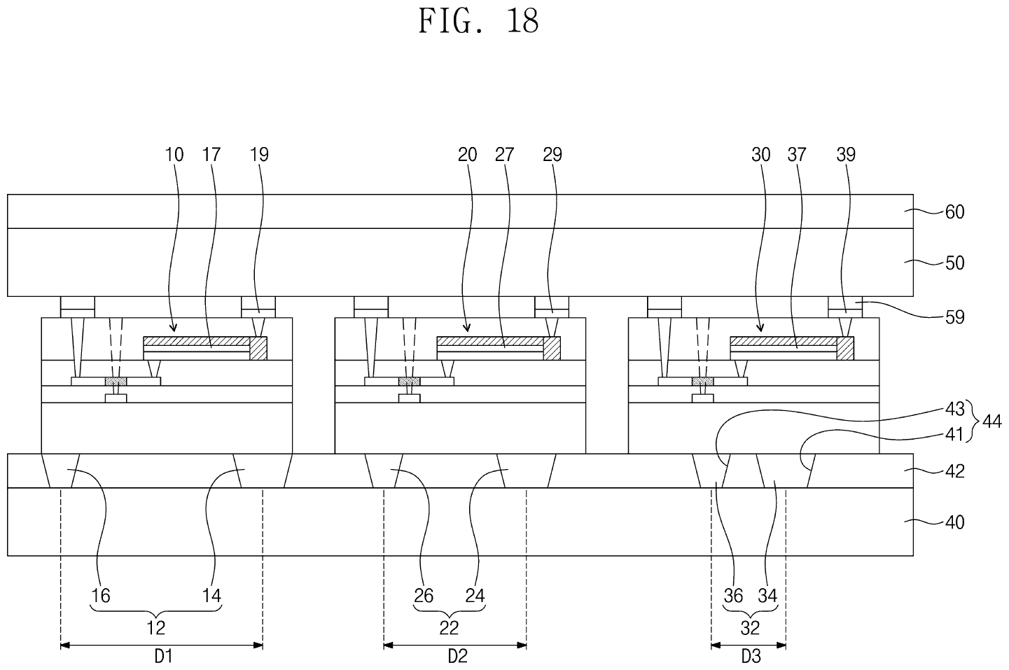

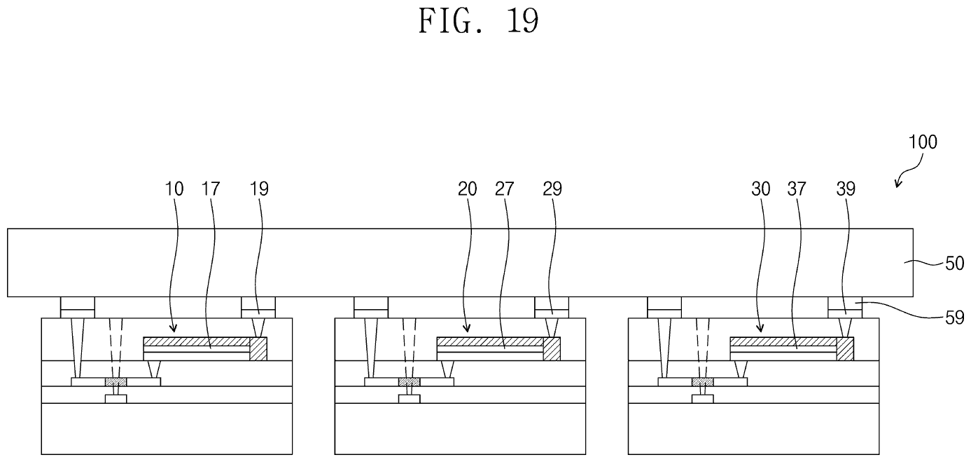

FIGS. 15 to 19 are cross-sectional views of processes of mounting and transferring the first unit device 10, the second unit device 20, and the third unit device 30 in FIGS. 5, 10, and 14.

Referring to FIGS. 1 and 15 to 17, the first unit device 10, the second unit device 20, and the third unit device 30 are mounted on a transfer substrate 40 (S40). The transfer substrate 40 may have an alignment pattern 42. The alignment pattern 42 may include a photoresist pattern. The alignment pattern 42 may have a plurality of trenches 44. The trenches 44 may expose a portion of a top surface of the transfer substrate 40. According to an embodiment, each of the plurality of trenches 44 may include a wide trench 41 and a narrow trench 43. The wide trench 41 may be wider than the narrow trench 43. A center of the narrow trench 43 may be provided at a first distance D1, a second distance D2, or a third distance D3 from a center of the wide trench 41. The wide trench 41 may accommodate each of the first wide key pattern 14, the second wide key pattern 24, and the third wide key pattern 34. The narrow trench 43 may accommodate each of the first narrow key pattern 16, the second narrow key pattern 26, and the third narrow key pattern 36.

The transfer substrate 40 may have different physical properties as the alignment pattern 42, and have the same physical properties as the first wide key pattern 14, the second wide key pattern 24, the third wide key pattern 34, the first narrow key pattern 16, the second narrow key pattern 26, and the third narrow key pattern 36. When the alignment pattern 42 has a hydrophobic property, each of the first wide key pattern 14, the second wide key pattern 24, the third wide key pattern 34, the first narrow key pattern 16, the second narrow key pattern 26, the third narrow key pattern 36, and the transfer substrate 40 has a hydrophilic property. Each of the first wide key pattern 14, the second wide key pattern 24, the third wide key pattern 34, the first narrow key pattern 16, the second narrow key pattern 26, and the third narrow key pattern 36 may slide with repulsion with respect to the alignment pattern 42. The first wide key pattern 14, the second wide key pattern 24, the third wide key pattern 34, the first narrow key pattern 16, the second narrow key pattern 26, and the third narrow key pattern 36 may be easily seated on the transfer substrate 40.

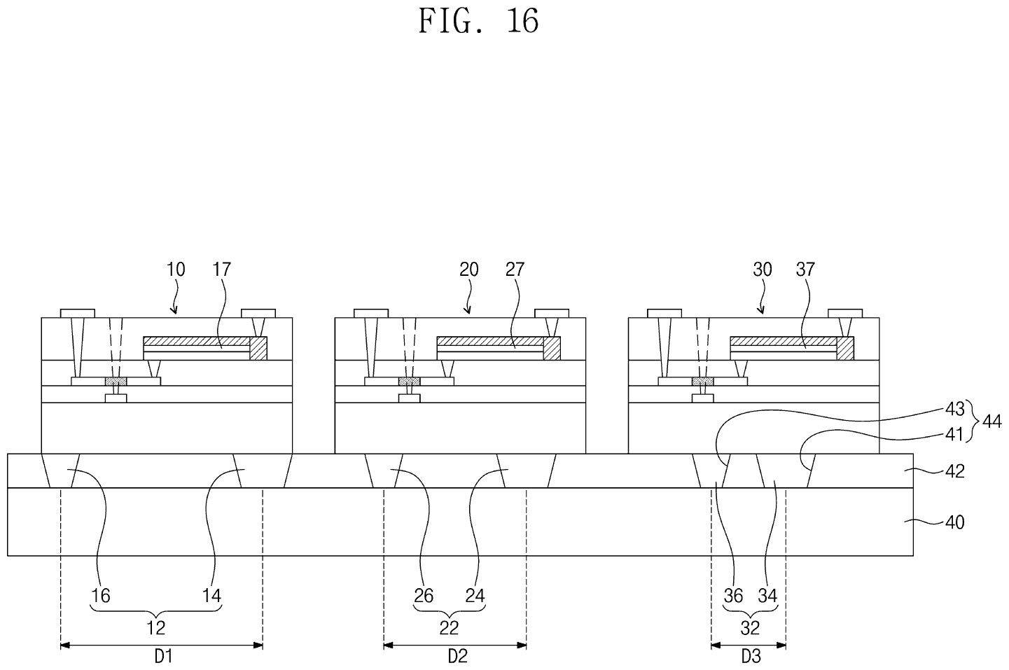

Referring to FIGS. 15 and 16, the first unit device 10, the second unit device 20, and the third unit device 30 may be provided in a fluid 46 and mounted on the transfer substrate 40 by using a self-assemble method. When the first unit device 10, the second unit device 20, and the third unit device 30 are introduced into the fluid 46 in a container, the fluid 46 may be stirred. The container may be shaken by an external force, and an embodiment of the inventive concept is not limited thereto. The first unit device 10, the second unit device 20, and the third unit device 30 may be dispersed in the fluid 46. The fluid 46 may be provided on the transfer substrate 40. The fluid 46 may include water, oil, or solvent, and an embodiment of the inventive concept is not limited thereto. The first unit device 10, the second unit device 20, and the third unit device 30 may be sunk in the fluid 46.

The first unit device 10 may be provided on the alignment pattern 42 of the wide trench 41 and the narrow trench 43 that are spaced the first distance D1 from each other. The wide trench 41 and the narrow trench 43 may accommodate the first wide key pattern 14 and the first narrow key pattern 16, respectively, to align an azimuth of the first unit device 10.

The second unit device 20 may be provided on the alignment pattern 42 of the wide trench 41 and the narrow trench 43 that are spaced the second distance D2 from each other. The wide trench 41 and the narrow trench 43 may accommodate the second wide key pattern 24 and the second narrow key pattern 26, respectively, to align an azimuth of the second unit device 20.

The third unit device 30 may be provided on the alignment pattern 42 of the wide trench 41 and the narrow trench 43 that are spaced the third distance D3 from each other. The wide trench 41 and the narrow trench 43 may accommodate the third wide key pattern 34 and the third narrow key pattern 36, respectively, to align an azimuth of the third unit device 30.

The first unit device 10, the second unit device 20, the third unit device 30, and the fluid 46, which are not self-assembled and remain on the transfer substrate 40, may be removed. Thereafter, in a case in which there is any empty trench 41 upon inspection of the transfer substrate 40, the introducing of and the removing of the first unit device 10, the second unit device 20, the third unit device 30, and the fluid 46 may be performed again. The introducing of and the removing of the first unit device 10, the second unit device 20, the third unit device 30, and the fluid 46 may be repeatedly performed until the empty trench 41 is not present.

As above, the first unit device 10, the second unit device 20, and the third unit device 30 may be mixed in the fluid 46 and then mounted together on the transfer substrate 40. Alternatively, the first unit device 10, the second unit device 20, and the third unit device 30 may be provided in different fluids from each other, and then mounted individually on the transfer substrate 40. That is, the first unit device 10 may be mixed in a first fluid and then mounted on the transfer substrate 40, the second unit device 20 may be mixed in a second fluid and then mounted on the transfer substrate 40, and the third unit device 30 may be mixed in a third fluid and then mounted on the transfer substrate 40.

The first unit device 10, the second unit device 20, and the third unit device 30 may be aligned on the transfer substrate 40 without the fluid 46 in FIG. 15.

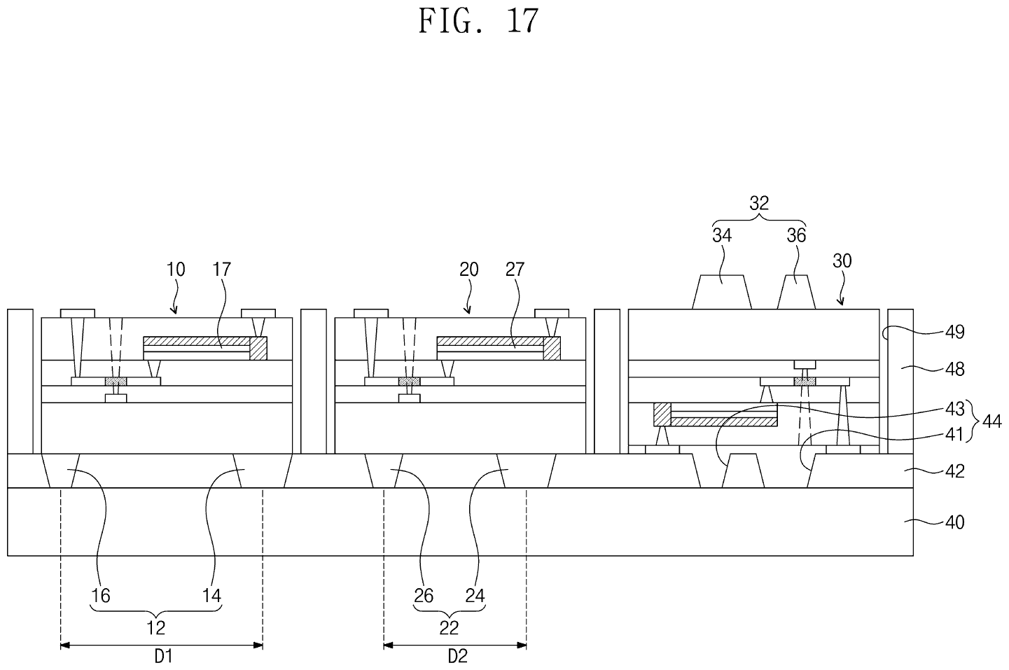

Referring to FIG. 17, the first unit device 10, the second unit device 20, and the third unit device 30 may be more easily aligned with the aid of a chip guiding mask 48. The chip guiding mask 48 may have mask holes 49. Each of the mask holes 49 may have a width greater than a width of each of the first unit device 10, the second unit device 20, and the third unit device 30 on a plan view. The first unit device 10, the second unit device 20, and the third unit device 30 may be provided in the mask holes 49, respectively. The first unit device 10, the second unit device 20, and the third unit device 30 may slide along inner sidewalls of the mask holes 49, respectively, and be mounted on the transfer substrate 40. The first unit device 10, the second unit device 20, and the third unit device 30 may each be re-aligned by the wide trench 41 and the narrow trench 43. For example, as illustrated in FIG. 17, the third unit device 30 may be misaligned. The misaligned third unit device 30 may be taken out from the mask hole 49 by an external picker (not illustrated). Thereafter, the third unit device 30 may be aligned and then provided in the mask hole 49 again.

Referring to FIGS. 1, 18, and 19, the first unit device 10, the second unit device 20, and the third unit device 30 are transferred to a stretchable substrate 50 (S50). The transfer substrate 40 may transfer the first unit device 10, the second unit device 20, and the third unit device 30 to the stretchable substrate 50. The stretchable substrate 50 may be fixed to a support substrate 60. For example, the stretchable substrate 50 may include a polymer resin. According to an embodiment, the stretchable substrate 50 may have a substrate pad 59. The substrate pad 59 may be bonded to each of the first pad 19, the second pad 29, and the third pad 39. The substrate pad 59 may include a solder bump. Although not illustrated, the stretchable substrate 50 may further have lines connected to the substrate pad 59.

Thereafter, the transfer substrate 40, the alignment pattern 42, and the support substrate 60 may be removed.

Thus, the method for manufacturing the stretchable display device 100 according to an embodiment of the inventive concept may increase production reliability by using the first alignment key patterns 12, the second alignment key patterns 22, and the third alignment key patterns 32 to align the first unit device 10, the second unit device 20, and the third unit device 30 on the transfer substrate 40.

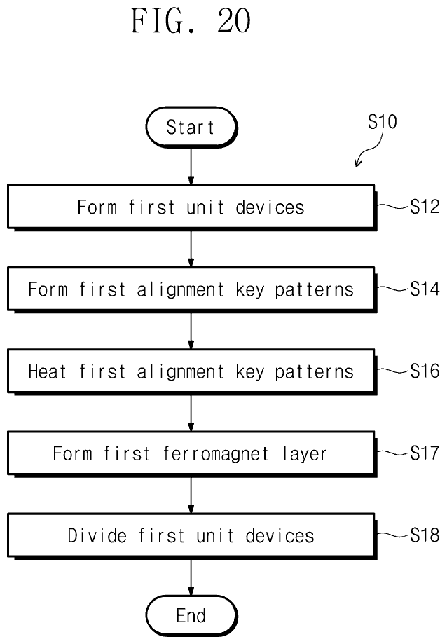

FIG. 20 illustrates a step of manufacturing the first unit devices 10 in FIG. 4 according to an embodiment (S10).

Referring to FIG. 20, the manufacturing of the first unit devices 10 (S10) may further include heating the first alignment key patterns 12 (S16), and forming a first ferromagnet layer 81 (see FIG. 22) (S17).

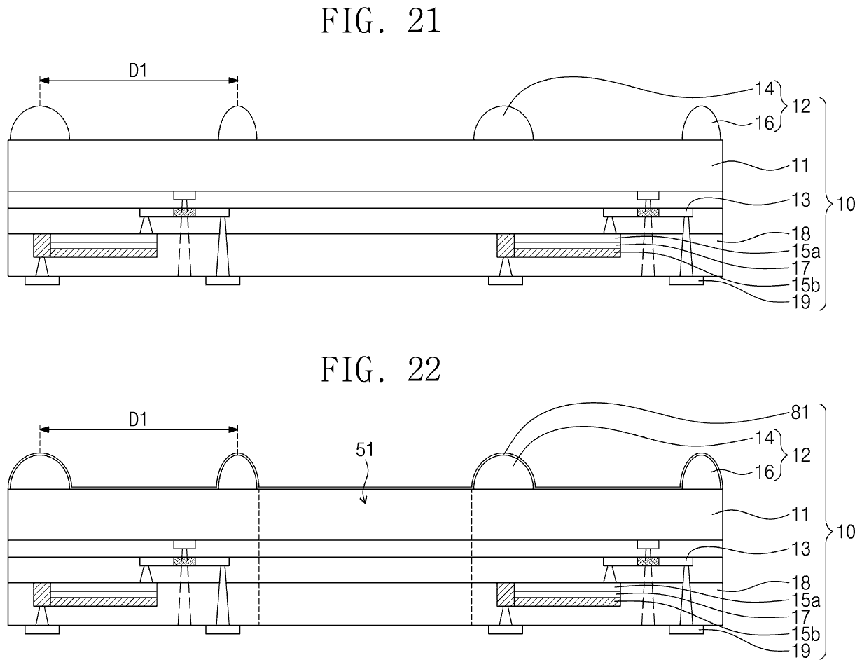

FIGS. 21 to 23 are cross-sectional views of a process for the first unit devices 10 in FIG. 4.

Referring to FIGS. 20 and 21, the first alignment key patterns 12 are heated (S16). The first alignment key patterns 12 may be heated at a temperature of about 80° C. to about 180° C. The first alignment key patterns 12 may be reflowed. The first alignment key patterns 12 may have a rounded top surface. Each of the first alignment key patterns 12 may have a semi-spherical shape.

Referring to FIGS. 20 and 22, the first ferromagnet layer 81 is formed on the first alignment key patterns 12 (S17). The first ferromagnet layer 81 may be formed by a physical vapor deposition method or a chemical vapor deposition method. For example, the first ferromagnet layer 81 may include nickel (Ni), iron (Fe), cobalt (Co), or an alloy thereof. The first alignment key patterns 12 may be reflowed at the same time as the forming of the first ferromagnet layer 81, and an embodiment of the inventive concept is not limited thereto.

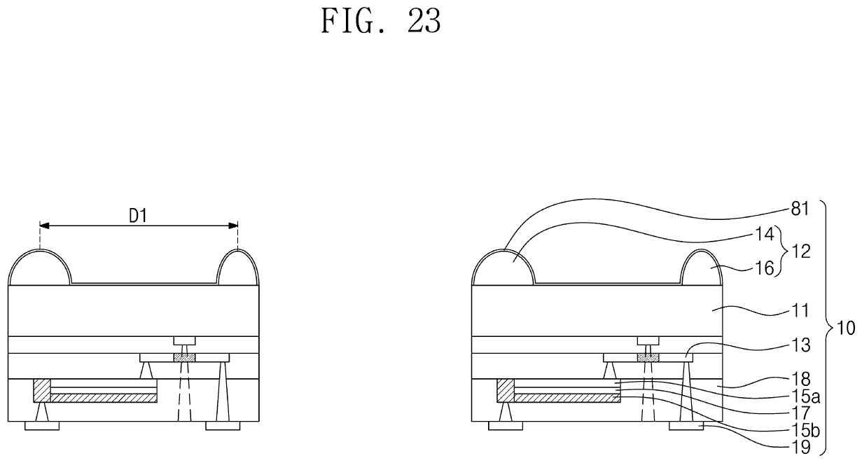

Referring to FIGS. 20 and 23, the first cutting region 51 is removed to divide the first unit devices 10 (S18). Then, the first ferromagnet layer 81 on the first cutting region 51 may be removed.

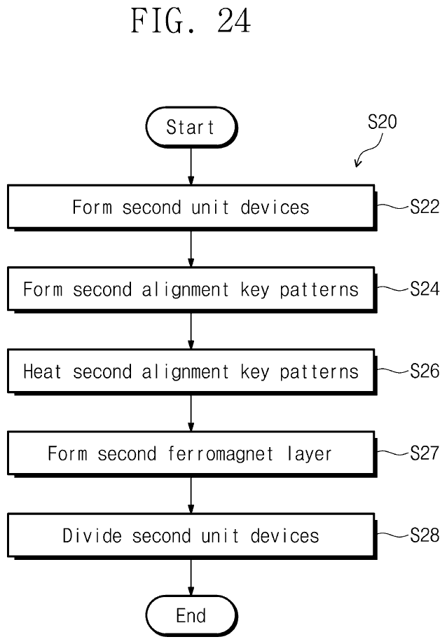

FIG. 24 illustrates a step of manufacturing the second unit devices 20 in FIG. 9 according to an embodiment (S20).

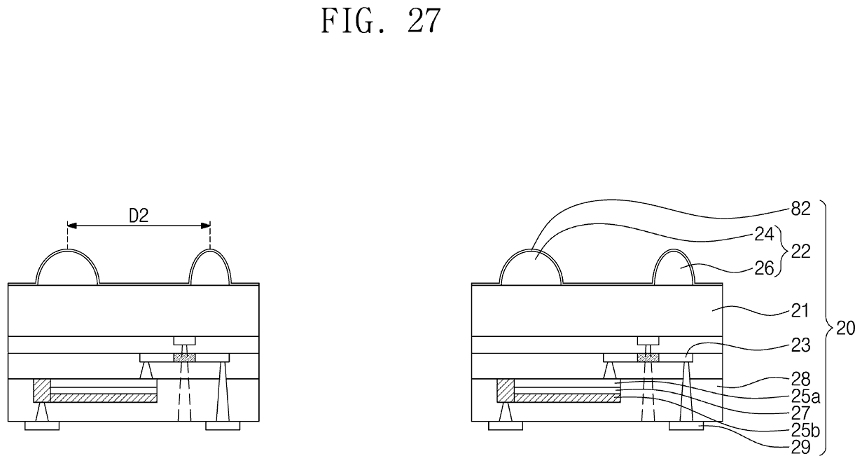

Referring to FIG. 24, the manufacturing of the second unit devices 20 (S20) may further include heating the second alignment key patterns 22 (S26), and forming a second ferromagnet layer 82 (see FIG. 26) (S27).

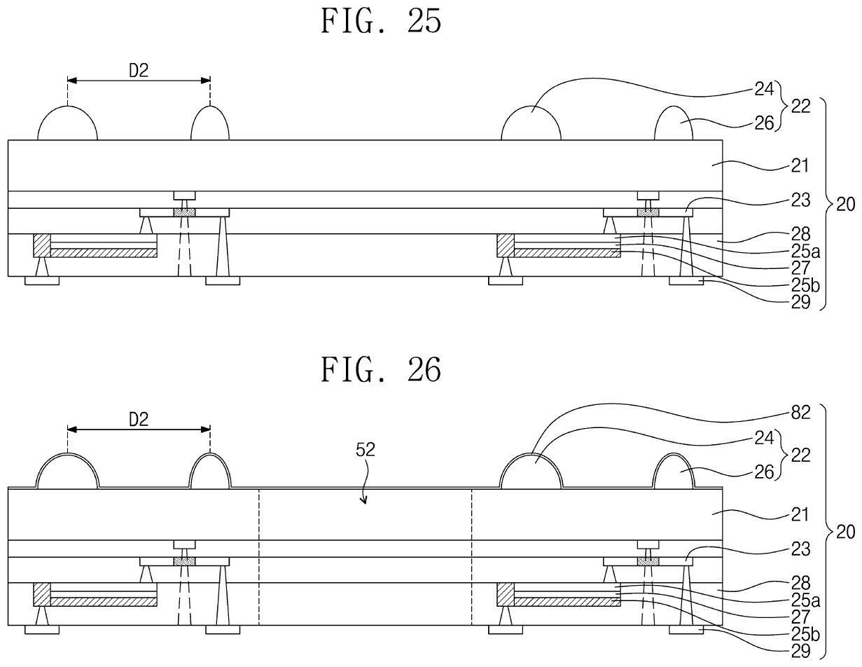

FIGS. 25 to 27 are cross-sectional views of a process for the second unit devices 20 in FIG. 9.

Referring to FIGS. 24 and 25, the second alignment key patterns 22 are heated (S26). The second alignment key patterns 22 may be heated at a temperature of about 80° C. to about 180° C. The second alignment key patterns 22 may be reflowed. The second alignment key patterns 22 may have a rounded top surface. Each of the second alignment key patterns 22 may have a semi-spherical shape.

Referring to FIGS. 24 and 26, the second ferromagnet layer 82 is formed on the second alignment key patterns 22 (S27). The second ferromagnet layer 82 may be the same as the first ferromagnet layer 81. The second ferromagnet layer 82 may be formed by a physical vapor deposition method or a chemical vapor deposition method. For example, the second ferromagnet layer 82 may include nickel (Ni), iron (Fe), cobalt (Co), or an alloy thereof. The second alignment key patterns 22 may be reflowed at the same time as the forming of the second ferromagnet layer 82, and an embodiment of the inventive concept is not limited thereto.

Referring to FIGS. 24 and 27, the second cutting region 52 is removed to divide the second unit devices 20 (S28). Then, the second ferromagnet layer 82 on the second cutting region 52 may be removed.

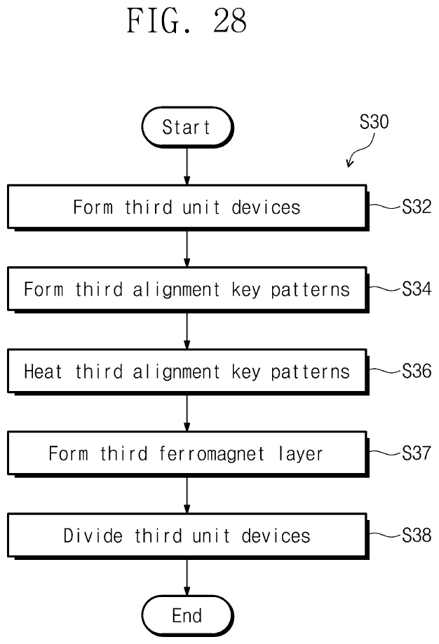

FIG. 28 illustrates a step of manufacturing the third unit devices 30 in FIG. 13 according to an embodiment (S30).

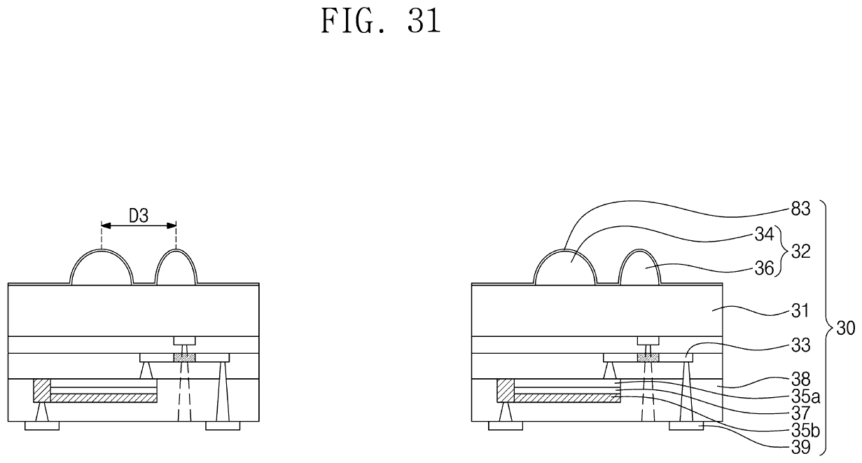

Referring to FIG. 28, the manufacturing of the third unit devices 30 (S30) may further include heating the third alignment key patterns 32 (S36), and forming a third ferromagnet layer 83 (see FIG. 30) (S37).

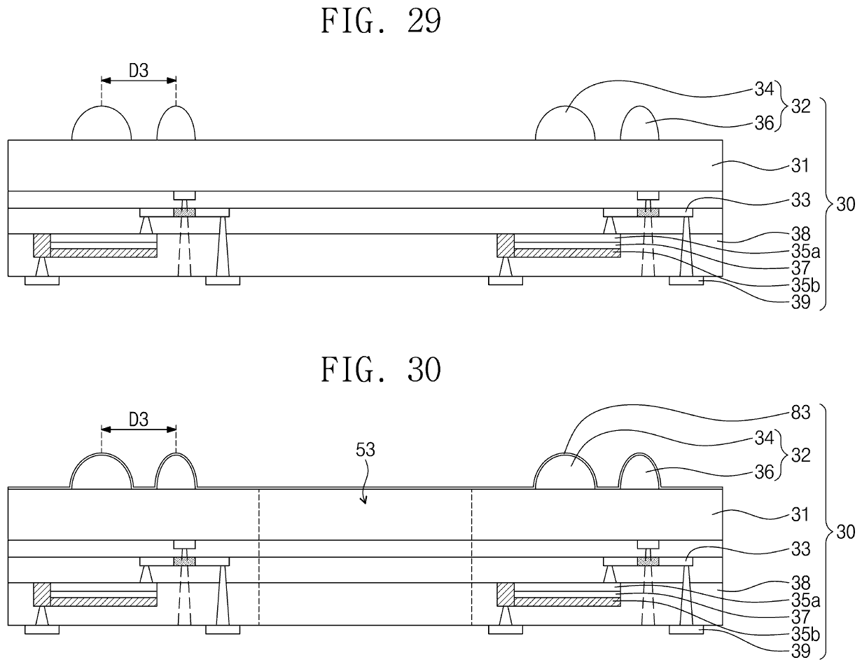

FIGS. 29 to 31 are cross-sectional views of a process for the third unit devices 30 in FIG. 13.

Referring to FIGS. 28 and 29, the third alignment key patterns 32 are heated (S36). The third alignment key patterns 32 may be heated at a temperature of about 80° C. to about 180° C. The third alignment key patterns 32 may be reflowed. The third alignment key patterns 32 may have a rounded top surface. Each of the third alignment key patterns 32 may have a semi-spherical shape.

Referring to FIGS. 28 and 30, the third ferromagnet layer 83 is formed on the third alignment key patterns 32 (S37). The third ferromagnet layer 83 may be the same as the first ferromagnet layer 81 and the second ferromagnet layer 82. The third ferromagnet layer 83 may be formed by a physical vapor deposition method or a chemical vapor deposition method. For example, the third ferromagnet layer 83 may include nickel (Ni), iron (Fe), cobalt (Co), or an alloy thereof. The third alignment key patterns 32 may be reflowed at the same time as the forming of the third ferromagnet layer 83, and an embodiment of the inventive concept is not limited thereto.

Referring to FIGS. 28 and 31, the third cutting region 53 is removed to divide the third unit devices 30 (S38). Then, the third ferromagnet layer 83 on the third cutting region 53 may be removed.

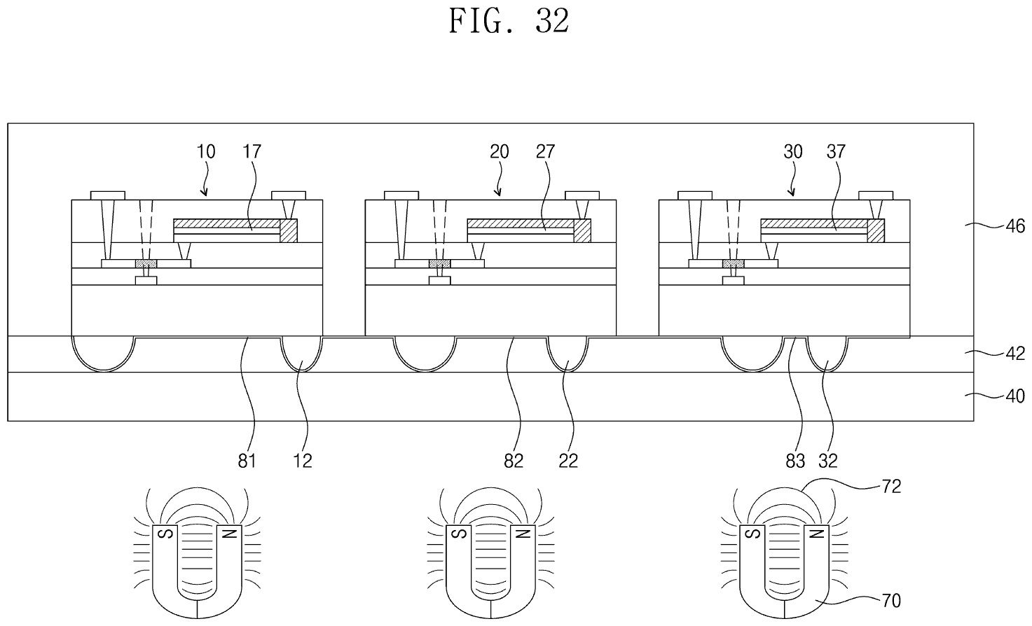

FIG. 32 illustrates the first unit device 10, the second unit device 20, and the third unit device 30, and the transfer substrate in FIG. 16 according to an embodiment.

Referring to FIGS. 1 and 32, a magnetic field 72 may be used to mount the first unit device 10, the second unit device 20, and the third unit device 30 on the transfer substrate 40 (S50). When the first unit device 10, the second unit device 20, the third unit device 30, and the fluid 46 are provided on the transfer substrate 40, the magnetic field 72 may be provided below the transfer substrate 40. The magnetic field 72 may be provided by a permanent magnet 70 or an electromagnet. The magnetic field 72 may induce a magnetic force with respect to the first ferromagnet layer 81, the second ferromagnet layer 82, and the third ferromagnet layer 83. When the first unit device 10, the second unit device 20, and the third unit device 30 are provided in the fluid 46, the magnetic field 72 may move the first alignment key patterns 12, the second alignment key patterns 22, and the third alignment key patterns 32 to the transfer substrate 40.

As described above, the method for manufacturing the stretchable display device according to the embodiment of the inventive concept may align the first to third unit devices, which include the first to third alignment key patterns different in distance between the wide key pattern and the narrow key pattern, on the transfer substrate by using the self-assemble method, thereby increasing the production reliability.

Although the embodiments of the present invention have been described with reference to the accompanying drawings, it is understood that the present invention should not be limited to these embodiments but various changes and modifications can be made by one ordinary skilled in the art without changing the technical idea or essential features. Therefore, it should be understood that the embodiments described above are intended to be illustrative and not for purposes of limitation in all aspects.

What is claimed is:

1. A method for manufacturing a stretchable display device, the method comprising:
manufacturing first to third unit devices including first to third alignment key patterns, respectively, each of which is provided in a pair and which are different in distance between the pair;
mounting the first to third unit devices, by using a self-assemble method, on a transfer substrate having trenches which accommodate the first to third alignment key patterns; and
transferring the first to third unit devices to a stretchable substrate.

2. The method of claim 1, wherein each of the first alignment key patterns comprises:
a first wide key pattern; and
a first narrow key pattern which is narrower than the first wide key pattern and spaced a first distance from the first wide key pattern.

3. The method of claim 2, wherein each of the second alignment key patterns comprises:
a second wide key pattern; and
a second narrow key pattern which is narrower than the second wide key pattern and spaced a second distance less than the first distance from the second wide key pattern.

4. The method of claim 3, wherein each of the third alignment key patterns comprises:
a third wide key pattern; and
a third narrow key pattern which is narrower than the third wide key pattern and spaced a third distance less than the second distance from the third wide key pattern.

5. The method of claim 2, wherein the first unit device further comprises a substrate having a rectangular shape,
wherein the first wide key pattern and the first narrow key pattern are arranged in a diagonal direction of the rectangular shape.

6. The method of claim 1, wherein the first to third unit devices are provided in a fluid and aligned on the transfer substrate.

7. The method of claim 1, wherein the first to third unit devices are provided in mask holes, respectively, and aligned on the transfer substrate.

8. The method of claim 1, wherein the first unit device comprises a red light emitting layer,
the second unit device comprises a green light emitting layer, and
the third unit device comprises a blue light emitting layer.

9. The method of claim 1, wherein each of the trenches comprises:
a wide trench; and
a narrow trench narrower than the wide trench.

10. The method of claim 1, wherein the first to third unit devices further comprise first to third ferromagnet layers provided on the first to third alignment key patterns, respectively.

11. A method for manufacturing a stretchable display device, the method comprising:
manufacturing first unit devices each including first alignment key patterns spaced a first distance from each other;
manufacturing second unit devices each including second alignment key patterns spaced a second distance less than the first distance from each other;
manufacturing third unit devices each including third alignment key patterns spaced a third distance less than the second distance from each other;
aligning the first to third unit devices, by using a self-assemble method, on a transfer substrate having trenches which accommodate the first to third alignment key patterns; and
transferring the first to third unit devices to a stretchable substrate.

12. The method of claim 11, wherein the manufacturing of the first unit devices comprises:
forming the first unit devices each including a first color light emitting layer on a first substrate;
forming, on a bottom surface of the first substrate, the first alignment key patterns including a first wide key pattern and a first narrow key pattern spaced the first distance from the first wide key pattern; and
cutting the first substrate to individually divide the first unit devices.

13. The method of claim 12, wherein the manufacturing of the first unit devices further comprises:
heating the first alignment key patterns; and
forming a first ferromagnet layer on the bottom surface of the first substrate and the first alignment key patterns.

14. The method of claim 11, wherein the manufacturing of the second unit devices comprises:
forming the second unit devices each including a second color light emitting layer on a second substrate;
forming, on a bottom surface of the second substrate, the second alignment key patterns including a second wide key pattern and a second narrow key pattern spaced the second distance from the second wide key pattern; and
cutting the second substrate to individually divide the second unit devices.

15. The method of claim 14, wherein the manufacturing of the second unit devices further comprises:
heating the second alignment key patterns; and
forming a second ferromagnet layer on the bottom surface of the second substrate and the second alignment key patterns.

16. The method of claim 11, wherein the manufacturing of the third unit devices comprises:
forming the third unit devices each including a third color light emitting layer on a third substrate;
forming, on a bottom surface of the third substrate, the third alignment key patterns including a third wide key pattern and a third narrow key pattern spaced the third distance from the third wide key pattern; and
cutting the third substrate to individually divide the third unit devices.

17. The method of claim 16, wherein the manufacturing of the third unit devices further comprises:
heating the third alignment key patterns; and
forming a third ferromagnet layer on the bottom surface of the third substrate and the third alignment key patterns.

18. The method of claim 11, wherein each of the trenches comprises:
a wide trench; and
a narrow trench narrower than the wide trench.

19. The method of claim 11, wherein the first to third alignment key patterns each comprise a photoresist pattern.

20. The method of claim 11, wherein the transfer substrate comprises an alignment pattern having the trenches,
wherein the alignment pattern comprises a photoresist pattern.
